(19) United States
(12) Patent Application Publication
(10) Pub. No.: US 2025/0355748 A1
(43) Pub. Date: Nov. 20, 2025

(54) FAULT DETECTION METHOD FOR NON-VOLATILE MEMORY AND APPARATUS, ELECTRONIC DEVICE AND STORAGE MEDIUM

(71) Applicant: SAMSUNG ELECTRONICS CO., LTD., Suwon-si (KR)

(72) Inventors: Yeyang WANG, Suwon-si (KR); Ni XUE, Suwon-si (KR)

(73) Assignee: SAMSUNG ELECTRONICS CO., LTD., Suwon-si (KR)

(21) Appl. No.: 18/739,586

(22) Filed: Jun. 11, 2024

(30) Foreign Application Priority Data
May 17, 2024 (CN) 202410619864.5

(51) Int. Cl. G06F 11/07; G06F 11/34

(52) U.S. Cl. CPC G06F 11/0781; G06F 11/0772; G06F 11/3452

(57) ABSTRACT

A fault detection method for a non-volatile memory, an apparatus, an electronic device and a storage medium are provided. The fault detection method for a non-volatile memory includes obtaining threshold voltage distribution data for a non-volatile memory to be detected, obtaining, from the threshold voltage distribution data, a data feature of each of a plurality of control line types, predicting a possibility of failure of each control line type based on the data feature of each control line type, to obtain a type prediction result, and performing a fault detection operation in the non-volatile memory based on the type prediction result of each control line type.

### BACKGROUND

The disclosure relates to a data storage technology, and in particular, to a fault detection method for a non-volatile memory, an apparatus, an electronic device and a storage medium.

In a non-volatile memory, a fault is generally caused by read/write interference, wear and tear in a programming or erasure (P/E) process, etc. After the memory is manufactured, the memory is tested for faults. However, at present, there are very limited fault detection methods in a factory test.

Specifically, in related art fault detection schemes, only a Word Line (WL) in a control line is usually detected, and based on its detection result, the overall fault situation of the memory is judged. However, the fault information that may be obtained based on the detection of a particular control line type is limited, making the fault detection result not accurate.

### SUMMARY

One or more aspect of the disclosure provides a fault detection method for a non-volatile memory, an apparatus, an electronic device and a storage medium, to at least solve the problem of the inaccurate fault detection result of the non-volatile memory in the above related technologies.

Additional aspects and/or advantages of the general idea of the disclosure will be set forth in the ensuing description in part, and still other parts will be clear through the description or may be known after the implementation of the general idea of the disclosure.

### BRIEF DESCRIPTION OF DRAWINGS

The above and other aspects and features of the exemplary embodiments of the disclosure will become clearer by the following description in conjunction with the accompanying drawings illustrating the exemplary embodiments, wherein:

FIG. 1 is a flowchart of a fault detection method for a non-volatile memory according to an exemplary embodiment of the disclosure;

FIG. 2 is a flowchart of a method of performing data dimensionality reduction in a fault detection method for a non-volatile memory according to an exemplary embodiment of the disclosure;

FIG. 3 illustrates a diagram of threshold voltage distribution data in a data dimensionality reduction process in a fault detection method for a non-volatile memory according to an exemplary implementation of the disclosure;

FIG. 4 is a diagram of threshold voltage distribution data in an interpolation completing process in a fault detection method for a non-volatile memory according to an exemplary embodiment of the disclosure;

FIG. 5 is a diagram of threshold voltage distribution data in a dimension completing process in a fault detection method for a non-volatile memory according to an exemplary embodiment of the disclosure;

FIG. 6 is a flowchart of a method of training a type fault detection model in a fault detection method for a non-volatile memory according to an exemplary embodiment of the disclosure;

FIG. 7 is an architectural diagram of an implementation of fault detection according to an exemplary embodiment of the disclosure;

FIG. 8 is a flowchart of a method of training a fusion model in a fault detection method for a non-volatile memory according to an exemplary embodiment of the disclosure;

FIG. 9 is a flowchart of a method of identifying a bad line in a fault detection method for a non-volatile memory according to an exemplary embodiment of the disclosure;

FIG. 10 is a flowchart of an abnormality scoring process in a fault detection method for a non-volatile memory according to an exemplary embodiment of the disclosure;

FIGS. 11A and 11B are flowcharts of a process of identifying a bad line in a fault detection method for a non-volatile memory according to an exemplary embodiment of the disclosure;

FIG. 12 is an architectural diagram of implementing a fault detection method for a non-volatile memory according to an exemplary embodiment of the disclosure;

FIG. 13 is a flowchart of an offline training model in a fault detection method for a non-volatile memory according to an exemplary embodiment of the disclosure.

FIG. 14 is a flowchart of online detection in a fault detection method for a non-volatile memory according to an exemplary embodiment of the disclosure.

FIG. 15 is a block diagram of a fault detection apparatus for a non-volatile memory according to an exemplary embodiment of the disclosure.

### DETAILED DESCRIPTION

Hereinafter, various embodiments will be described in detail with reference to the accompanying drawings.

The following specific embodiments are provided to assist readers in obtaining a full understanding of methods, devices, and/or systems described herein. However, various changes, modifications, and equivalents of the methods, devices, and/or systems described herein will be clear upon understanding the disclosure of the present application. For example, orders of operations described herein are merely exemplary and the disclosure is not limited to those set forth herein, but rather may be altered as will be clear upon an understanding of the disclosure of the present application, except for operations that must occur in a particular order. In addition, descriptions of features known in the art may be omitted for greater clarity and brevity.

The features described herein may be implemented in different forms and should not be construed as being limited to examples described herein. Rather, the examples described herein have been provided to illustrate only some of many feasible ways of realizing the methods, devices, and/or systems described herein, many feasible ways will be clear upon an understanding of the disclosure of the present application.

The terms used herein are used only to describe various examples and will not be used to limit the disclosure. Unless the context clearly indicates otherwise, the singular form is also intended to include the plural form. The terms “comprising,” “including” and “having” indicate the presence of recited features, quantities, operations, components, elements, and/or combinations thereof, but do not preclude the presence or addition of one or more other features, quantities, operations, components, elements, and/or combinations thereof.

Unless otherwise defined, all terms used herein, including technical and scientific terms, have the same meanings as those commonly understood by those of ordinary skill in the art to which the disclosure pertains after understanding the disclosure. Unless expressly so defined herein, terms (e.g., terms defined in a general-purpose dictionary) should be interpreted as having a meaning consistent with their meaning in the context of the relevant field and the disclosure, and should not be interpreted ideally or in an overly formalistic manner.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

The embodiments of the disclosure are example embodiments, and thus, the disclosure is not limited thereto, and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

As previously mentioned, in the related art fault detection schemes, the fault detection result of the non-volatile memory is not sufficiently accurate.

For example, in some fault detection schemes applied in a solid state drive (SSD), a weak wordline (WL) detection module may be provided for detecting a weak WL that is susceptible to failure. In this manner, it is proposed that a service life of an SSD may be extended by protecting a weak word line (WL). The weak WL detection module may maintain a weak WL list based on a bit error rate (BER) value of the WL, so that in a case in which several weak WLs that are most prone to failure are requested, a desired WL may be quickly identified.

However, in such fault detection schemes, only one data type may be considered. For example, in the actual factory test, while various control lines may be associated with a memory fault, these related art schemes only consider the WL, and fault information that may be obtained based on this type of data line is limited, leading to an inaccurate test result. Moreover, these related art schemes are not sufficiently automated and intelligent, and a series of thresholds need to be set to identify the weak WL, and the setting of these thresholds relies on manual experience, which not only consumes manual resources, but also may lead to inaccurate threshold setting due to differences in experience, which in turn leads to the inaccurate test result. In addition, this scheme is also unable to identify a specific bad line in the memory where a fault exists.

In another related art scheme, a method for detecting and localizing a fault in a 3D NAND flash memory is proposed, in which, a voltage and current flowing through a string in a memory block may be collected, and for different types of fault detection, a fault in the memory block is detected using a corresponding method based on the collected voltage and current and a corrective action is initiated to respond to the specific fault.

However, in such a scheme, the identifying level is limited, and it may only detect a fault at the block level, and cannot directly identify a specific bad line; on the other hand, the scheme cannot directly detect the fault based on the monitoring data already available in the current testing process, and requires an additional processing process, such as performing new charging process and the like for the SSD and then carrying out fault detection, which results in a lower detection efficiency.

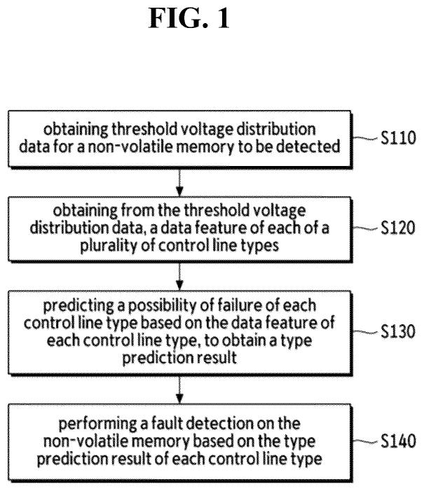

According to one or more aspects of the disclosure, a fault detection method for a non-volatile memory is provided, which may address the above-described problems and other problems in the related art fault detection techniques. FIG. 1 is a flowchart of a fault detection method for a non-volatile memory according to an exemplary embodiment of the disclosure. For example, the fault detection method may include the operations illustrated in FIG. 1. However, the disclosure is not limited thereto, and as such, according to another embodiment, one or more other operations may be performed, one or more operations may be omitted, and one or more operations may be combined:

At operation S110, the method may include obtaining threshold voltage distribution data. For example, the threshold voltage distribution data may be for anon-volatile memory on which a fault detection operation is to be performed. For example, the threshold voltage distribution data may be used to detect a fault in the a non-volatile memory.

As an example, the non-volatile memory may be a NAND flash solid state drive (SSD), however the disclosure is not limited thereto, and as such, according to another embodiment, the non-volatile memory may be other types of non-volatile memory.

In the example case in which the non-volatile memory is the NAND flash SSD, the threshold voltage distribution data may be NAND threshold voltage distribution (NAND Vth Distribution) data.

The reliability of the NAND flash SSD may be directly affected by NAND failures, which may be caused by read/write interferences, wear and tear during P/E, etc. For example, these failures will be reflected at least to a certain extent in changes in the NAND threshold voltage distribution, such as widening, overlapping, left-shifting, right-shifting, etc. The NAND threshold voltage distribution data is commonly used to represent NAND characteristics. For example, in a plot of the NAND threshold voltage distribution, the horizontal axis may be a voltage value, and the vertical axis may be a number of cells under a certain voltage value Vth, and the form of the NAND threshold voltage distribution is generally similar to a normal distribution.

At operation S120, the method may include obtaining a data feature of one or more control line types in the non-volatile memory. Here, a control line type may refer to a type of control line in the non-volatile memory. The data feature of each of the one or more control line types may be obtained based on the threshold voltage distribution data. For example, the method may include extracting the data feature of each of the one or more control line types from the threshold voltage distribution data.

According to an embodiment, the non-volatile memory may include a plurality of control line types. For example, the control line types may include, but is not limited to, a word line (WL), a dummy line (DL) a ground select line (GSL), and a string select line (SSL). For example, the WL may be connected to a memory cell in the respective line, the DL may be used to prevent interference between neighboring cells during a programming or erasing operation, the GSL may be connected to a ground select line transistor in the respective cell string, and the SSL may be connected to a string select transistor in each cell string.

For example, the data feature may be capable of reflecting a threshold voltage distribution for each control line type.

According to the embodiment, the data feature of each control line type may be obtained by performing data dimensionality reduction on data under each data dimension based on the threshold voltage distribution data of a plurality of control lines under the control line type.

For example, the data dimensionality reduction may refer to an operation of reducing the amount of data under each data dimension so that the total amount of data is reduced.

For example, under each control line type, there may be a plurality of control lines, and each of the plurality of control lines may have corresponding threshold voltage distribution data.

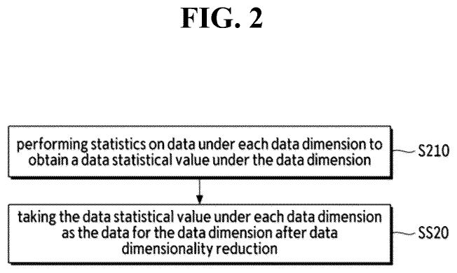

According to an embodiment, FIG. 2 illustrates a method of performing data dimensionality reduction on the data under each data dimension. For example, according to an embodiment, in operation S210, the method may include performing statistics on the data under each data dimension to obtain a data statistical value under the data dimension. In operation S220, the method may include taking the data statistical value under each data dimension as the data for the respective data dimension after the data dimensionality reduction. For example, the data for each of the data dimension may be the data statistical value under each data dimension after the data dimensionality reduction.

As described above, there may be a plurality of control lines for each control line type, and in operation S210, statistics may be performed on the threshold voltage distribution data of these control lines in accordance with the data dimension, so as to simplify the amount of data under each data dimension.

Here, the statistical value of the data under each data dimension may reflect the data characteristics of each control line under the data dimension. As an example, the data statistical value may be the maximum value of the data under this data dimension. For example, the maximum value among data values of all control lines under of a particular control line type may be selected as the data statistical value for each data dimension. However, the embodiments of the disclosure are not limited thereto, and the statistical value of the data may, for example, also be an average value, a mean square deviation, and the like.

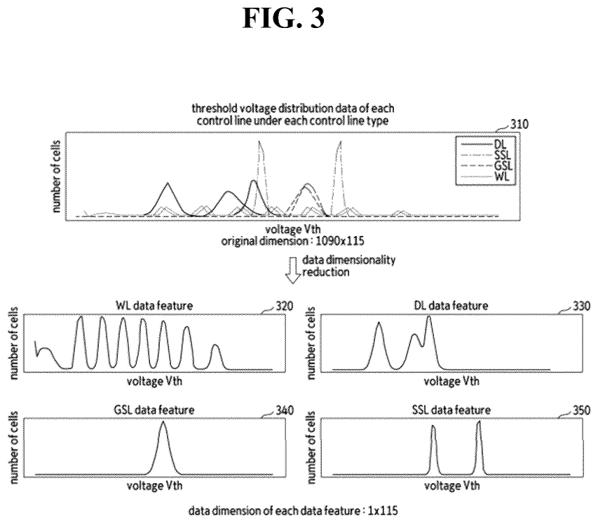

FIG. 3 illustrates a diagram of threshold voltage distribution data in a data dimensionality reduction process according to an exemplary implementation of the disclosure.

The top graph 310 in FIG. 3 illustrates threshold voltage distribution data for four types of control lines, WL, DL, GSL, and SSL. For example, the threshold voltage distribution data may be, for example, distribution data after missing value completion, which will be described in more detail below. According to an embodiment, there may be a plurality of control lines under each control line type. The data dimensionality reduction may be performed on each data dimension for each control line type to obtain a final data feature of each control line type.

Taking the data statistical value being the maximum value as an example, as shown in the four graphs (320, 330, 340 and 350) below in FIG. 3, for each control line type, the maximum value of the data under each data dimension may be selected as a dimensionality reduction feature of each control line type, so as to obtain a distribution curve for each control line type. Here, in the case where the data statistical value is the maximum value, taking the maximum value of the data under each data dimension may reflect a deviation from normal data more obviously, so that a fault maybe detected easily.

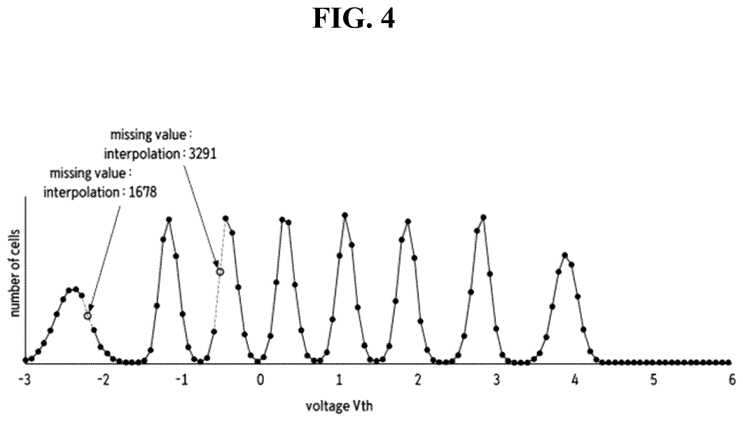

As can be seen by comparing the original graph 310 at the top of FIG. 3 with the four curve graphs 320, 330, 340 and 350 after data dimensionality reduction, the original threshold voltage distribution data is two-dimensional data of 1090×115, where a length of each data dimension is 115 (i.e., the threshold voltage distribution data for each control line includes 115 sampling points), and there are a total of 1,090 pieces of threshold voltage distribution data under the four control line types (i.e., a total of 1090 control lines). The dimension of the data may be reduced through data dimensionality reduction processing, while retaining the physical meaning embodied in the data distribution. The final generated data features include four data features with a data dimension of 1×115 (i.e., the four graphs 320, 330, 340 and 350 below in FIG. 3), corresponding to the four control line types respectively, which may be used as inputs to a fault detection model for each control line type (described in detail below). Here, FIG. 3 (and FIGS. 4, 5, 10, and 11 below) is intended to illustrate an example of the distribution relationship between voltage Vth and the number of cells, and as such, the specific unit of the voltage Vth on the horizontal axis, and the specific value for the number of cells on the vertical axis, are not given in FIG. 3 (and FIGS. 4, 5, 10, and 11 below).

According to an embodiment, the threshold voltage distribution data of each control line may be normalized before the data dimensionality reduction is performed, so that the data dimensionality reduction may be performed on the normalized data.

Through the above data dimensionality reduction, the amount of data may be reduced and the computing speed of the detection algorithm may be improved, and at the same time, valuable information in the threshold voltage distribution data may be retained. For example, the overall distribution of the threshold voltage may be retained to ensure the accuracy of the subsequent fault detection.

In addition, in the threshold voltage distribution data, the data dimensions of different control lines under the same control line type may be different (i.e., the number of sampling points of the voltage data may be different), but the sampling point intervals of the voltage data are the same. Therefore, before performing data dimensionality reduction on the data under each data dimension, the threshold voltage distribution data of each control line under the same control line type may be aligned in order to enable the data dimensionality reduction to be more accurate.

According to an embodiment, before performing the data dimensionality reduction on the data under each data dimension, a missing value completion operation may be performed on the threshold voltage distribution data of each control line under the control line type such that the data dimension of the completed distribution data of each control line is the same. For example, the same data dimension represents the same number of sampling points.

According to an embodiment, the data dimension of each control line under the same control line type may be processed as the same dimension by the missing value completion, so that voltage values (e.g., the horizontal coordinates in the threshold voltage distribution) of data points of each control line under the same control line type may be aligned to facilitate subsequent processing.

According to an embodiment, the operation of completing the missing value completion may include completing missing values in the threshold voltage distribution data by interpolation. According to an embodiment, the operation of completing the missing value completion may include completing the threshold voltage distribution data of the control line by utilizing a default value such that the completed data dimension of the control line is equal to the maximum data dimension. For example, in a case in which a data dimension of a control line is less than a maximum data dimension, the operation of completing the missing value completion may include completing the threshold voltage distribution data of the control line by utilizing a default value such that the completed data dimension of the control line is equal to the maximum data dimension. In an example, the maximum data dimension is the maximum voltage range covered by all control lines under the control line type of the control line.

For example, the missing data values in the threshold voltage distribution data may be calculated by an interpolation method. Here, the interpolation method may be, for example, a third order spline interpolation method, but it is not limited thereto, and other interpolation methods such as polynomial interpolation, linear interpolation, and the like may also be used.

FIG. 4 illustrates an example of a threshold voltage distribution of a WL control line, in which, some data values are missing at some data dimensions (or sampling points). In such a case, in order to facilitate the subsequent data dimensionality reduction process, the third order spline interpolation method may be used for the interpolation computation, to complete the missing values, so as to make the data in the whole (or entire) data dimensions complete, i.e., there are values in each data dimension (or sampling point).

Alternatively or additionally, according to another embodiment, the data dimensions of the different control lines may be different, in which case the longest data dimension covered by each control line (i.e., the maximum voltage range) may be used as a base value for missing value completion for each control line, utilizing a default value.

Here, the default value may be, for example, 0, but the disclosure is not limited to thereto, and as such, according to another embodiment, the default value may also be other values given according to practical needs.

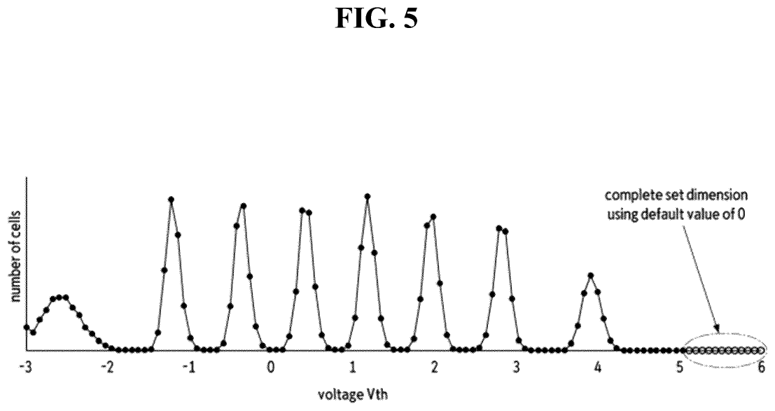

FIG. 5 illustrates a threshold voltage distribution of a certain WL control line, in which, the maximum voltage range covered by all control lines of a particular control line type may be [−3, 6], whereas the voltage range of the control line shown in FIG. 4 is [−3, 5]. As such, the default value of 0 may be utilized to complete the set dimension [5, 6].

As another example, a voltage range covered by a control line A may be [−2, 6], while a voltage range covered by a control line B may be [−3, 7]. In order to facilitate the subsequent data dimensionality reduction, data values of the control line A within [−2, −3] and [6, 7] may be completed so that the voltage range of the control line A is the same as that of the control line B.

In the illustration above, the missing values in the threshold voltage distribution data may be completed to align the data dimensions of each control line under the same control line type, which is conducive to improving the accuracy of the subsequent data dimensionality reduction.

Although the missing values are completed for the data of each control line prior to the data dimensionality reduction according to an embodiment, the disclosure is not limited thereto, and as such, according to another embodiment, the process of completing the missing values is not necessary, and the process of completing the missing values may also be omitted in the case where the threshold voltage distribution data of the control line is complete. According to another embodiment, a way of deleting a part of the data may be used so that the threshold voltage distribution data of each control line under the same control line type is aligned, for example, in the case where a data value of a certain data dimension of a certain control line is missing, data values of other control lines in that data dimension may be deleted.

Referring to FIG. 1, at operation S130, the method may include obtaining a possibility of failure of each of the one or more control line types. For example, a possibility of failure of each control line type may be predicted based on the data feature of each control line type to obtain a type prediction result.

According to an embodiment, a possibility of failure of each control line type may be predicted separately for each control line type. For example, a pre-trained type fault detection model may be utilized for the prediction.

For example, operation S130 may include inputting the data feature of each control line type into a corresponding type fault detection model, respectively, performing fault prediction through the corresponding type fault detection model, and obtaining the type prediction result of failure of each control line type, respectively.

As an example, the type fault detection model for each control line type may adopt a supervised machine learning algorithm. For example, such a supervised machine learning algorithm may include, but is not limited to, a random forest algorithm, which has high accuracy and good robustness. For different control line types, models with the same algorithm may be used for the prediction, or models with different algorithms may be used for the prediction.

According to an embodiment, in a training process of the model, each type fault detection model may be trained separately and independently using the data of the control line of the corresponding control line type in historical data. For example, the training process of the model may be training process of the model may be performed offline and/or periodically using the data of the control line of the corresponding control line type in historical data. The output of each type fault detection model may be a probability that a fault exists for the corresponding control line type.

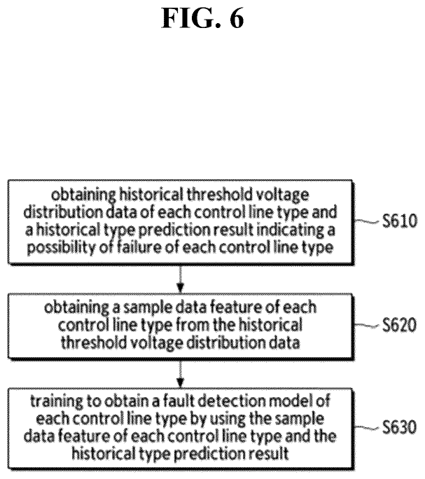

FIG. 6 illustrates an example of a method of training the type fault detection model for each control line type according to an embodiment.

At operation S610, the method may include obtaining historical threshold voltage distribution data and a historical type prediction result. For example, the historical threshold voltage distribution data of each control line type and the historical type prediction result indicating a possibility of failure of each control line type may be obtained. For example, the historical threshold voltage distribution data may include normal data for which a fault detection result is an absence of a fault and fault data for which the fault detection result is an existence of a fault. That is, the normal data refers to data without a fault and the fault data refers to data with a fault.

As an example, the fault detection method according to the exemplary embodiment of the disclosure may be divided into two part, an online workflow and an offline workflow. For example, in the online workflow, a current type fault detection model may be used to participate in the fault detection of the memory, and a corresponding fault detection result may be obtained. The fault detection result may include normal data in which a fault is absent f and fault data in which a fault is present. The fault detection result and the corresponding threshold voltage distribution data may be applied to the offline workflow to train the current type fault detection model and obtain a new type fault detection model for use in updating the current type fault detection model.

However, the exemplary embodiment of the disclosure is not limited to this, and as such, according to another embodiment, the historical threshold voltage distribution data and the corresponding historical fault detection result may also be obtained in other ways. For example, the historical threshold voltage distribution data and the corresponding historical fault detection result may also be data obtained through other detection processes.

At operation S620, the method may include obtaining a sample data feature based on the historical threshold voltage distribution data. For example, the sample data feature of each control line type may be extracted from the historical threshold voltage distribution data.

For example, the sample data feature for each control line type may be extracted by the process of data dimensionality reduction described above. The sample data feature may reflect the threshold voltage distribution of the corresponding control line type in the historical threshold voltage distribution data.

At operation S630, the method may include training a fault detection model based on the sample data feature and the historical type prediction result. For example, the fault detection model of each control line type may be trained and obtained by using the sample data feature of each control line type and the historical type prediction result.

Here, a supervised machine learning algorithm may be used to train and obtain the corresponding fault detection model by using the sample data feature of each control line type and the historical type prediction result.

As an example, the fault detection model for each control line type described herein, as well as a fusion model and a scoring model to be described below, may be trained and obtained in the same process, which will be described in detail below.

Here, through the type fault detection models for each control line type separately, the automated prediction of the possibility of failure of each control line type may be realized for use in combining the type prediction result for each type to predict the possibility of a fault for the memory as a whole.

Although the prediction of each control line type using the pre-trained type fault detection model is described above according to an embodiment, the disclosure is not limited thereto, and as such, according to another embodiment, other methods may be used for the prediction, such as fault prediction rules may be pre-set separately for each control line type, so as to determine the type prediction result.

Returning to the reference to FIG. 1, at operation S140, the method may include performing a fault detection on the non-volatile memory based on the type prediction result of each control line type. For example, the fault in the non-volatile memory may be detected based on the type prediction result of each control line type.

According to an exemplary embodiment of the disclosure, a fault analysis may be performed for each control line type so as to comprehensively determine a fault situation of the memory.

For example, the operation S140 may include inputting the type prediction result of each control line type into a fusion model, performing fault detection through the fusion model, and obtaining a fault detection result of the non-volatile memory.

Here, the fusion model may be used to fuse the type prediction result of each control line type to analyze the overall failure of the memory based on the fault situation of each control line type in the memory.

As an example, the fusion model may fuse the type prediction results of the type fault detection models by means of single-layer stacking to obtain a final fault detection result. The type prediction result of each type fault detection model may be used as an input to the fusion model. The output of the fusion model may be the probability of the presence of a fault in the memory.

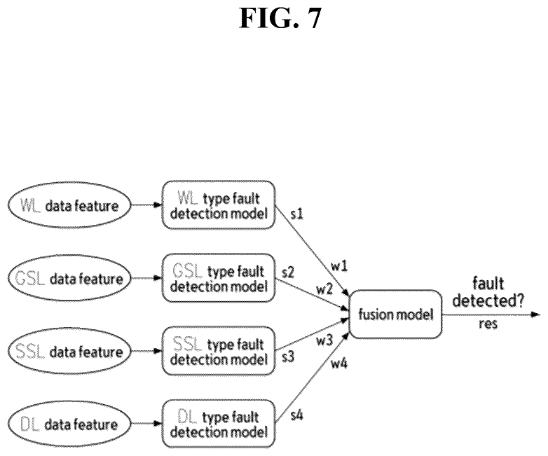

FIG. 7 illustrates a combination of an architecture of the type fault detection model and the fusion model according to an embodiment. For example, the output of the fusion model may be expressed by the following equation:

$$res = f ( {\sum }_{i = 1}^{n} {w}_{i} * {s}_{i} ) ,$$

where res represents the final output result of the fusion model, wᵢ represents a weight of the ith type prediction result, s, represents the input ith type prediction result, f represents an activation function, and n represents the total number of control line types. As an example, n may be 4, for example, including WL, GSL, SSL, and DL, however, the disclosure is not limited thereto. As an example, a softmax function may be, but is not limited to, used as the activation function.

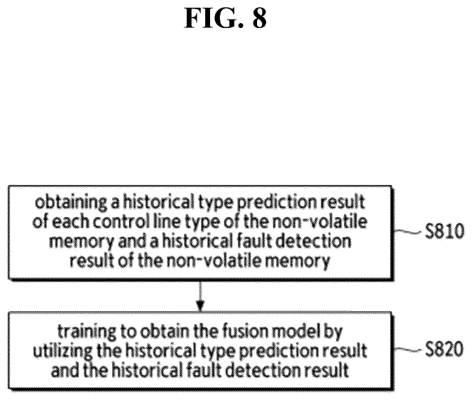

The training process of the above fusion model may be similar to that of a single-layer neural network. For example, FIG. 8 illustrates a method of training a fusion model according to an embodiment.

At operation S810, the method may include obtaining a historical type prediction result and a historical fault detection result. For example, the historical type prediction result of each control line type of the non-volatile memory and the historical fault detection result of the non-volatile memory may be obtained.

At operation S820, the method may include training a fusion model based on the historical type prediction result and the historical fault detection result. For example, the fusion model may be trained and obtain by utilizing the historical type prediction result and the historical fault detection result.

As an example, as described above, the fault detection method according to the exemplary embodiment of the disclosure may be divided into two-part, an online workflow and an offline workflow. For example, in the online workflow, a pre-trained type fault detection model may be used to predict each control line type and a corresponding type prediction result may be obtained as the historical type prediction result. The type prediction result may be inputted into the current fusion model, and the corresponding fault detection result is obtained as the historical fault detection result. The historical type prediction result and the corresponding historical fault detection result may be applied to the offline workflow to train the current fusion model to obtain a new fusion model for updating the current fusion model.

Since all control lines of all control line types are important, in the above-described method, the final fault detection result may be obtained by separately detecting the respective type fault detection models of the various control line types and then using the fusion model, in such a way as to improve the detection accuracy by taking into account comprehensive effect of the control lines of all control line types on the final fault detection result. However, the disclosure is not limited thereto, and as such, according to another embodiment, the final fault detection result may be obtained by detecting the type fault detection models of the various control line types in a combined manner.

Although an operation fusing the type prediction results of each control line type using a pre-trained fusion model to obtain the fault detection result of the memory is described above according to an embodiment, the disclosure is not limited thereto, and as such, according to another embodiment, other methods may be used for fusion. For example, the other methods may include, but is not limited to, the type prediction results of each control line type may be weighted in accordance with a pre-set weight, and the weighted type prediction results may be superimposed, and the fault detection result of the memory may be determined based on the result of the superimposition.

The above describes the process of determining the fault detection result of the memory in the fault detection method according to the exemplary embodiment of the disclosure, and based on which, in the case that a fault is detected in the non-volatile memory, the fault detection method according to the exemplary embodiment of the disclosure may also identify a bad line in the non-volatile memory.

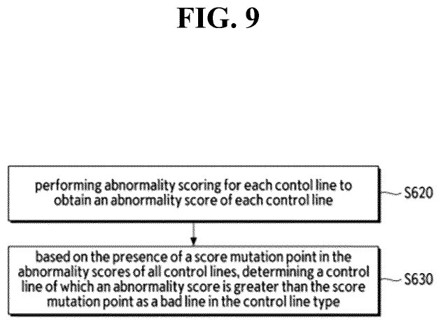

FIG. 9 illustrates a method performed for each control line type based on detecting an existence of a fault in the non-volatile memory:

At operation S910, the method may include performing abnormality scoring. For example, the abnormality scoring may be performed for each control line to obtain an abnormality score of each control line.

In the abnormality scoring operation, a possibility that an abnormality exists for each control line may be analyzed, and the abnormality score for each control line may represent a degree of abnormality for the control line. Here, the abnormality score may be, for example, a probability of an existence of an abnormality for a control line, however the disclosure is not limited thereto, and as such, the abnormality score may be represented in other ways.

As an example, in the operation S910, the threshold voltage distribution data for each control line may be input to the scoring model, and the abnormality score for each control line is obtained by performing abnormality scoring through the scoring model

Here, the scoring model may be a pre-trained machine learning model, which may be, for example, but not limited to, an Isolation Forest model, an Auto Encoder (AE) model, and the like. For different control line types, the scoring may be performed using models with the same algorithm or with different algorithms. In addition, here, the corresponding scoring model may be trained separately for each control line type, or one scoring model may be trained for all control line types.

As an example, the scoring model is trained and obtained by: obtaining historical normal threshold voltage distribution data of the non-volatile memory; training to obtain the scoring model by utilizing the historical normal threshold voltage distribution data in an unsupervised learning manner.

For example, the scoring model may be trained using the normal threshold voltage distribution data using the unsupervised learning method to enable the scoring model to learn the data feature of the fault-free normal control line, and in an example case in which the scoring model is utilized to perform abnormality scoring for a control line to be scored, the abnormality score of this control line may be determined based on a degree of deviation of the data feature of this control line relative to the data feature of the normal control line learned by the model.

As an example, as described above, the fault detection method according to the exemplary embodiment of the disclosure may be divided into two part, an online workflow and an offline workflow. In the offline workflow, the scoring model for each control line type may be trained separately and independently periodically using normal data without faults in the historical threshold voltage distribution data, i.e., normal samples.

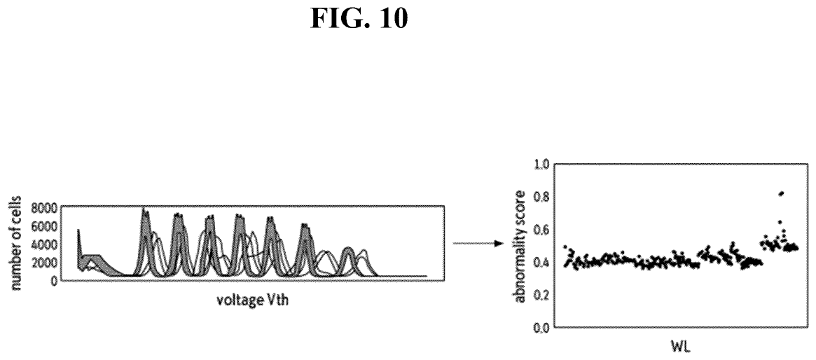

FIG. 10 illustrates an abnormality scoring process using a word line as an example. As shown in FIG. 10, the abnormality scoring may be performed separately for each control line using an isolated forest model to obtain an abnormality score for each control line (as shown in the right side of FIG. 10).

According to an exemplary embodiment of the disclosure, in the case of detecting the presence of a fault in the memory, by performing the abnormality scoring for the control lines, the degree of abnormality present in each control line may be predicted, thereby facilitating the identification of a bad line that caused the memory fault.

At operation S920, the method may include determining a control line, which has an abnormality score is greater than a score mutation point, as a bad line in the control line type. For example, in response to the presence of a score mutation point in the abnormality scores of all control lines, a control line of which an abnormality score is greater than the score mutation point is determined as a bad line in the control line type.

For example, whether a score mutation point exists in the abnormality scores may be determined by analyzing the abnormality scores of all control lines. For example, the score mutation point may be, for example, but is not limited to, a point that deviates furthest from the other abnormality scores, a point where the abnormality score rises rapidly, and the like. For example, the score mutation point may be a point above a threshold value or a point where a rate of rise of the abnormality score is above a reference rate.

As an example, the abnormality scores for all control lines may be sorted, and the score mutation point may be determined among the sorted abnormality scores.

Here, the abnormality scores of all control lines may be sorted from small to large or from large to small, so that an overall distribution of the abnormality scores may be observed. Based on such sorting, the last mutation point score in the distribution of abnormality scores may be found as an abnormality score threshold, and a control line of which the abnormality score is higher than this abnormality score threshold may be considered as a bad line.

According to an embodiment, as an example, an offline change point detection method such as a Cumulative Sum (CUSUM) method, a Bayesian method, and the like may be used to determine the score mutation point, however the disclosure is not limited thereto, and as such, according to another embodiment, and the score mutation point may also be determined by a slope change situation. For example, the score mutation point may be an abnormality score of which a slope relative to the previous abnormality score is greater than a predetermined slope threshold.

For example, through determining the abnormality score threshold by searching for the score mutation point, all possibly faulty control lines higher than the score mutation point may be selected, thereby avoiding leakage detection and improving the accuracy of bad line identification.

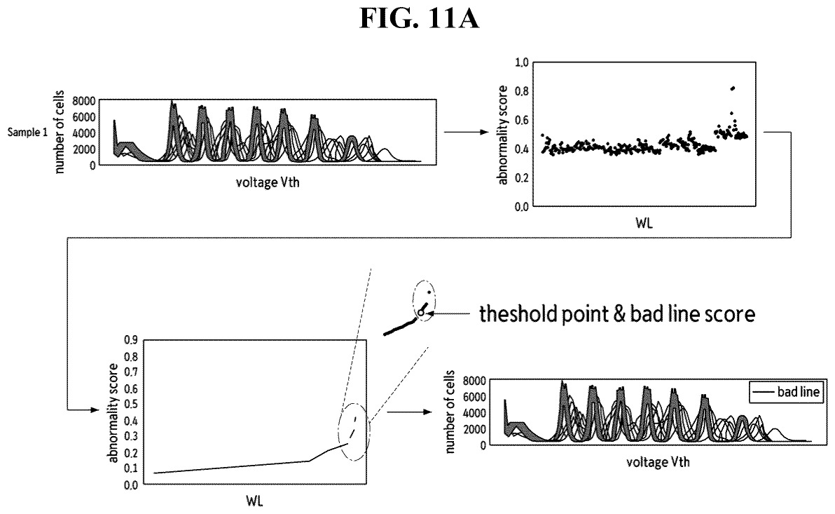

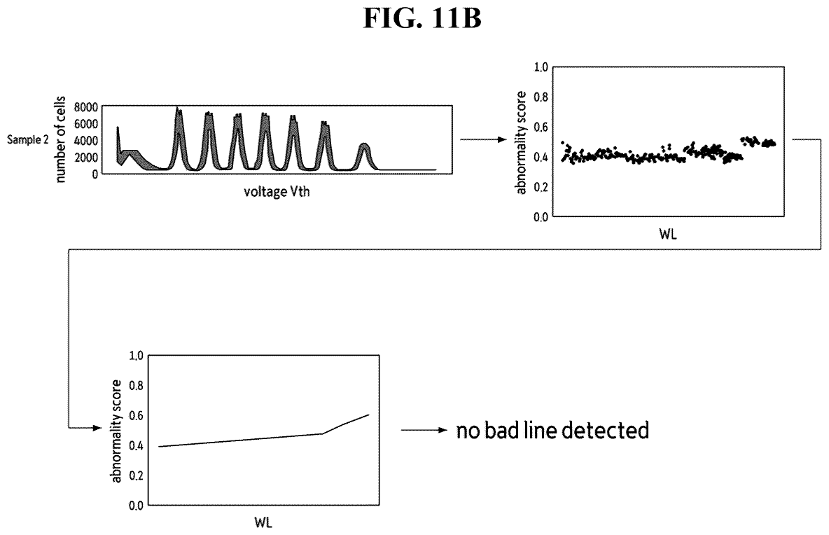

FIGS. 11A and 11B illustrate flowcharts of a process of identifying a bad line in a fault detection method for a non-volatile memory according to an embodiment. Taking a word line of FIG. 11A as an example, in Sample 1, by sorting the abnormality scores, based on an existence of a score mutation point in the sorted abnormality scores, the score mutation point may be used as a threshold point for the abnormality scores, and all control lines of which the abnormality scores are greater than the abnormality score threshold may be detected as bad lines. In Sample 2, by sorting the abnormality scores, it may be determined that there is no score mutation point in the sorted abnormality scores, and thus it may be considered that there is no bad line among these control lines.

With the above bad line identification method, it is possible to specifically locate a control line in which a fault occurs based on a determination that there is the fault in the memory, so as to facilitate subsequent processing such as maintenance of the memory.

Furthermore, based on the absence of the score mutation point in the abnormality scores of all control lines, it is determined that there is no bad line in that control line type.

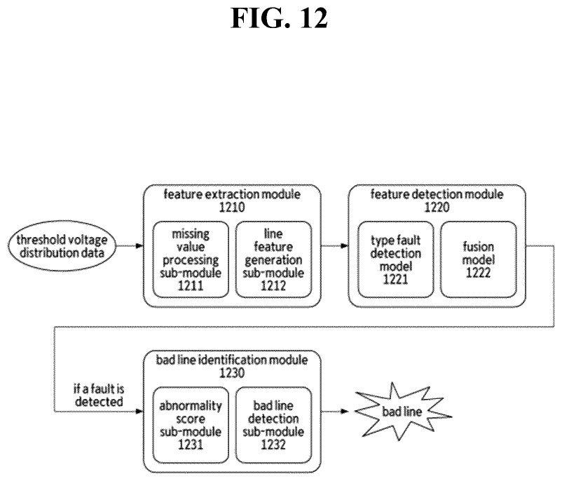

FIG. 12 illustrates an architecture for implementing a fault detection method for a non-volatile memory according to an embodiment of the disclosure.

As shown in FIG. 12, the architecture may include a feature extraction module 1210, a fault detection module 1220, and a bad line identification module 1230. According to an embodiment, the feature extraction module 1210, the fault detection module 1220, and the bad line identification module 1230 may be realized as hardware components and/or software components such as programs, software code or algorithms executable on one or more processor.

The feature extraction module 1210 may include a missing value processing sub-module 1211 and a line feature generation sub-module 1212. The missing value processing sub-module 1211 may pad the threshold voltage distribution data with different dimensions of each control line type, such that the data dimensions of each control line in each control line type are the same. The line feature generation submodule 1212 may extract corresponding features from the threshold voltage distribution data after missing value processing according to control line type to generate final data features for each control line type. For example, the line feature generation submodule 1212 may perform data dimensionality reduction and extract the corresponding features based on the data dimensionality reduction.

The fault detection module 1220 may perform fault detection of the memory. For example, the fault detection module 1220 may receive the data features of each control line type generated by the feature extraction module 1210 as the input, and may output an indication on whether a memory fault is detected. As an example, the fault detection module 1220 may include a type fault detection model 1221 and a fusion model 1222 described above, the specific implementation of which has been described above, and therefore will not be repeated here.

The bad line identification module 1230 may identify a bad line in each control line type in the threshold voltage distribution data. The bad line identification module 1230 may include an abnormality score sub-module 1231 and a bad line detection sub-module 1232. The abnormality score sub-module 1231 may include the scoring model as described above, and the bad line detection sub-module 1232 may identify the bad line of each control line based on the abnormality scores output from the scoring model.

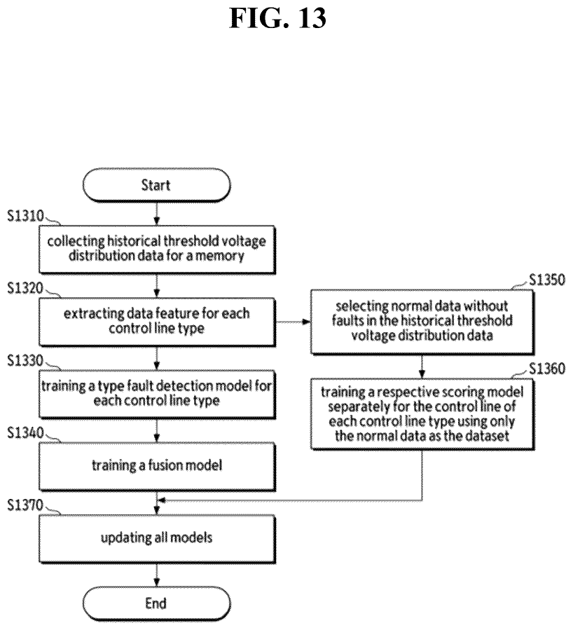

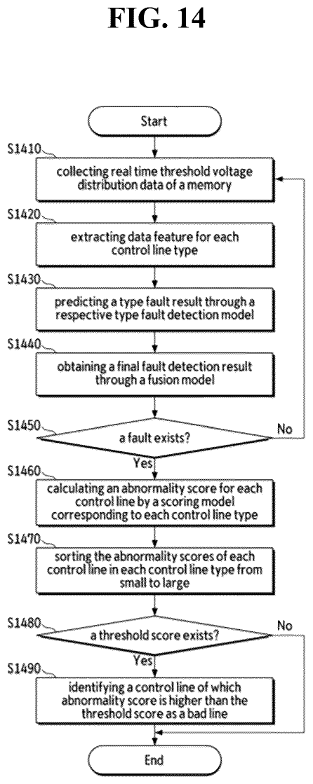

FIGS. 13 and 14 illustrate flowcharts of offline training a model and online detection, respectively, in a fault detection method in a non-volatile memory according to an exemplary embodiment of the disclosure.

For example, as mentioned above, the overall flow of the fault detection method according to the exemplary embodiment of the disclosure may include an offline task processing flow (Offline Workflow) and an online detection processing flow (Online Workflow). The offline workflow is responsible for training and updating models used in the fault detection method. The online workflow is responsible for performing real-time fault detection and bad line identification during testing of the memory using the models generated by the offline workflow.

The offline workflow may run periodically, the type fault detection model, the fusion model, and the scoring model are trained and updated using historical threshold voltage distribution data for a recent period of time as a dataset. For example, the recent period of time may be for the last 3 months.

For example, as shown in FIG. 13, at operation S1310, historical threshold voltage distribution data may be collected for a memory within a certain time range.

At operation S1320, control lines in the historical threshold voltage distribution data may be divided according to control line types, and a feature may be extracted for each control line type separately.

At operation S1330, a type fault detection model for each control line type may be trained by using the feature for each control line type, respectively.

At operation S1340, a fusion model may be trained based on the outputs of the respective type fault detection models by a stacking method.

At operation S1350, normal data without faults in the historical threshold voltage distribution data may be selected.

At operation S1360, a scoring model may be trained for the control line of each of the control line types using the normal data as the dataset. For example, the respective scoring model may be trained separate for the control line of each of the control line types using only the normal data.

At operation S1370, all corresponding old models may be updated with the trained new models.

In the online detection processing flow, the threshold voltage distribution data of all non-volatile memories being tested may be collected in real time, and the fault detection and bad line identification of the non-volatile memories may be performed by the fault detection method proposed in an exemplary embodiment of the disclosure.

For example, as shown in FIG. 14, at operation S1410, threshold voltage distribution data of anon-volatile memory being tested may be collected in real time.

At operation S1420, features of each control line type in the threshold voltage distribution data may be extracted separately.

At operation S1430, a type prediction result may be obtained for each control line type based on a respective type fault detection model.

At operation S1440, the respective type prediction results may be input into a fusion model to obtain a final fault detection result.

At operation S1450, the method may include determining whether a fault is detected in the memory. For example, in a case in which the fault detection result indicates that a fault is detected in the memory, the method proceeds to operation S1460; otherwise, the method returns to operation S1410.

At operation S1460, an abnormality score for each control line may be calculated by a scoring model corresponding to each control line type.

At operation S1470, the abnormality scores of each control line in each control line type may be sorted from small to large, such as detecting a score mutation point as a threshold score for a bad line by a mutation point detection algorithm.

In an example case in which a threshold score of the bad line exists in operation S1480, at operation S1490, a control line of which the abnormality score is higher than the threshold score may be identified a bad line. In an example case in which the threshold score of the bad line does not exist in operation S1480, there is no bad line in the data of that control line type.

Adopting the fault detection method of the above exemplary embodiment a precision may be higher than 0.8, a recall may be higher than 0.6, and an F0.5 score may be higher than 0.8. In addition, by fusing the results of respective type fault detection models, the result is better compared to the result of using only a single control line type, especially in terms of the recall, which means that the method is capable of detecting more faults than using only a single control line type indicator.

Furthermore, in the related art techniques, if a test case fails due to fault detection, the tester examines the threshold voltage distribution data to find the root cause. Since this task is highly dependent on manual experience, it makes the testing of the memory much less efficient. In this regard, by adopting the fault detection method of the above exemplary embodiment, faults may be automatically detected and bad lines may be identified instead of manual work, and the time cost of analyzing the faults of a single test case may be reduced from a few days to a few seconds, which greatly improves the efficiency of memory testing.

The fault detection method according to the exemplary embodiment of the disclosure may detect faults during memory testing more accurately, and may also identify bad lines in threshold voltage distribution data, improving the efficiency of memory testing and fault analysis.

For example, to address the problem that related art techniques consider fewer data types and contain limited fault information in fault detection, the fault detection method according to the exemplary embodiment of the disclosure may analyze faults for various control line types, and thus the method not only uses the WL, but also takes into account all control line types in the threshold voltage distribution data, such as the DL, the GSL, the SSL, and the like, thereby possible fault scenarios may be covered more comprehensively.

In addition, in the case of considering various control line types, the data dimension may be high, and the data dimension may not necessarily be the same for different models of memory, in this regard, the fault detection method according to the exemplary embodiment of the disclosure may perform a dimensionality reduction on the data, which retains valuable physical significance of the data while reducing the number of dimensions of the data, and thereby reduces time complexity of solving, and reduces the consumption of resources.

In addition, the fault detection method according to the exemplary embodiment of the disclosure may automatically and intelligently detect memory faults and identify bad lines by introducing various models, in which there is no need to set any threshold parameter and domain knowledge experience, and directly outputs whether the memory is faulty or not and marks a specific bad line. In addition, the fault detection method may also improve the accuracy of the fault detection result by fusing the type prediction results.

In addition, the fault detection method according to the exemplary embodiment of the disclosure may output the fault detection result in real time at the end of the test without additional processing flow, improving the overall testing efficiency of the memory.

In addition, the fault detection method according to the exemplary embodiment of the disclosure may detect faults and identify bad lines more comprehensively, quickly, and accurately during memory testing by introducing a machine learning method, and may improve the accuracy of the detection result by training and updating each model.

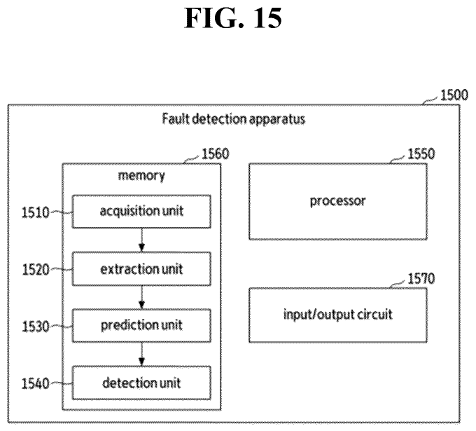

According to another aspect of an exemplary embodiment of the disclosure, there is provided a fault detection apparatus 1500 for a non-volatile memory, as shown in FIG. 15. According to an embodiment, the fault detection apparatus 1500 may include a processor 1550, a memory 1560 and an input/output circuit 1570. However, the disclosure is not limited thereto, and as such, the fault detection apparatus 1500 may include one or more other components. According to an embodiment, the memory 1560 may store one or more instruction set, programs or software units, which may be executed by the processor 1550 to perform various operations of the fault detection apparatus 1500. For example, the memory 1560 include an acquisition unit 1510, an extraction unit 1520, a prediction unit 1530, and a detection unit 1540. However, the disclosure is not limited thereto, and as such, according to another embodiment, the acquisition unit 1510, the extraction unit 1520, the prediction unit 1530, and the detection unit 1540 may be implemented as hardware components, for example, in the processor 1550. According to an embodiment, the acquisition unit 1510, the extraction unit 1520, the prediction unit 1530, and the detection unit 1540 may be referred to as an acquisition circuit, an extraction circuit, a prediction circuit, and a detection circuit respectively.

The acquisition unit 1510 may be configured to obtain threshold voltage distribution data for a non-volatile memory on which a fault detection operation is to be performed. For example, the acquisition unit 1510 may be configured to obtain threshold voltage distribution data to detect a fault in the a non-volatile memory.

The extraction unit 1520 may be configured to extract, from the threshold voltage distribution data, a data feature of each of a plurality of control line types.

The prediction unit 1530 may be configured to predict a possibility of failure of each control line type based on the data feature of each control line type, to obtain a type prediction result.

The detection unit 1540 may be to detect a fault in the non-volatile memory based on the type prediction result of each control line type.

As an example, the extraction unit is further configured to extract the data feature of each control line type by performing data dimensionality reduction on data under each data dimension based on the threshold voltage distribution data of a plurality of control lines under the control line type to obtain the data feature of the control line type.

As an example, the extraction unit is further configured to: before performing the data dimensionality reduction on the data under each data dimension, perform missing value completion on the threshold voltage distribution data of each control line under the control line type such that the data dimension of the completed distribution data of each control line is the same, wherein the same data dimension represents the same number of sampling points.

As an example, the missing value complementation includes: completing a missing value in the threshold voltage distribution data by interpolation; and/or in response to a data dimension of a control line being less than a maximum data dimension, completing the threshold voltage distribution data of the control line by utilizing a default value such that the completed data dimension of the control line is equal to the maximum data dimension, wherein the maximum data dimension is the maximum voltage range covered by all control lines under the control line type of the control line.

As an example, the extracting unit is further configured to perform the data dimensionality reduction on the data under each data dimension by performing statistics on the data under each data dimension to obtain a data statistical value under the data dimension, and taking the data statistical value under each data dimension as the data for the data dimension after the data dimensionality reduction.

As an example, the prediction unit is further configured to: input the data feature of each control line type into a corresponding type fault detection model, respectively, perform fault prediction through the corresponding type fault detection model, and obtain the type prediction result of failure of each control line type, respectively.

As an example, the type fault detection model of each control line type is trained and obtained by obtaining historical threshold voltage distribution data of each control line type and a historical type prediction result indicating a possibility of failure of each control line type, wherein the historical threshold voltage distribution data includes normal data for which a fault detection result is an absence of a fault and fault data for which the fault detection result is an existence of a fault, extracting a sample data feature of each control line type from the historical threshold voltage distribution data, and training to obtain the fault detection model of each control line type by using the sample data feature of each control line type and the historical type prediction result.

As an example, the detection unit is further configured to: input the type prediction result of each control line type into a fusion model, perform fault detection through the fusion model, and obtain a fault detection result of the non-volatile memory.

As an example, the fusion model is trained and obtained by obtaining a historical type prediction result of each control line type of the non-volatile memory and a historical fault detection result of the non-volatile memory, and training to obtain the fusion model by utilizing the historical type prediction result and the historical fault detection result.

As an example, the fault detection device further includes a bad line determination unit, the bad line determination unit may be to: in response to detecting the presence of a fault in the non-volatile memory, for each control line type: perform abnormality scoring for each control line to obtain an abnormality score of each control line; in response to the presence of a score mutation point in the abnormality scores of all control lines, identify a control line with an abnormality score greater than the score mutation point as a bad line in the control line type.

As an example, the bad line determining unit is further configured to: input the threshold voltage distribution data of each control line into a scoring model, perform abnormality scoring by the scoring model, and obtain the abnormality score of each control line.

As an example, the scoring model is trained and obtained by obtaining historic al normal threshold voltage distribution data of the non-volatile memory, and training to obtain the scoring model by utilizing the historical normal threshold voltage distribution data in an unsupervised learning manner.

As an example, the non-volatile memory is a NAND flash solid state disk, and the threshold voltage distribution data is NAND threshold voltage distribution data.

With respect to the apparatus in the above embodiment, the specific manner in which each unit performs an operation has been described in detail in the embodiment relating to the method, and will not be described in detail herein.

It should be understood that the individual units/modules in the storage method and storage apparatus according to the exemplary embodiments of the disclosure may be realized as hardware components and/or software components. One of skill in the art may, for example, use a field programmable gate array (FPGA) or an application-specific integrated circuit (ASIC) to implement the individual units/modules, depending on the processing performed by the respective unit/module being defined.

According to a further aspect of exemplary embodiments of the disclosure, there is provided a computer-readable storage medium storing a computer program, wherein the computer program, when is executed by a processor, implements the fault detection method for the non-volatile memory as described in the disclosure.

For example, the fault detection method for non-volatile memory according to exemplary embodiments of the disclosure may be written as a computer program, code segment, instruction, or any combination thereof, and recorded, stored, or fixed in or on one or more non-transitory computer-readable storage media. The computer-readable storage medium is any data storage device that may store data read out by a computer system. Examples of computer-readable storage media include: a read-only memory, a random access memory, a read-only CD-ROM, a magnetic tape, a floppy disk, an optical data storage device, and a carrier (such as a data transmission over the Internet via a wired or wireless transmission path).

According to yet another aspect of exemplary embodiments of the disclosure, there is provided an electronic device, wherein the electronic device includes: at least one processor, at least one memory storing computer-executable instructions, wherein the computer-executable instructions, when run by the at least one processor, cause the at least one processor to perform the fault detection method for the non-volatile memory as described in the disclosure.

For example, the electronic device may be broadly defined as a tablet, a smartphone, a smartwatch, or any other electronic device having the necessary computing and/or processing capabilities. In one embodiment, the electronic device may include a processor, a memory, a network interface, a communication interface, etc. connected via a system bus. The processor of the electronic device may be used to provide the necessary computing, processing, and/or control capabilities. The memory of the electronic device may include a non-volatile storage medium and an internal memory. The non-volatile storage medium may have stored in or on it an operating system, a computer program, and the like. The internal memory may provide an environment for operation of an operating system and the computer program in the non-volatile storage medium. A network interface and a communication interface of the electronic device may be used to connect and communicate with an external device via a network.

1. A fault detection method comprising:
obtaining threshold voltage distribution data corresponding to a non-volatile memory;
obtaining, based on the threshold voltage distribution data, a data feature of each of a plurality of control line types in the non-volatile memory;
predicting a possibility of failure of one or more of the plurality of control line types based on the data feature of the one or more of the plurality of control line types, to obtain a type prediction result for the one or more of the plurality of control line types; and
performing a fault detection operation on the non-volatile memory based on the type prediction result of each of the one or more of the plurality of control line types.

2. The fault detection method according to claim 1, wherein the data feature of each of the plurality of control line types is obtained by:
performing, based on the threshold voltage distribution data, data dimensionality reduction on data in each of a plurality of data dimensions for each of a plurality of control lines of each of the plurality of control line types.

3. The fault detection method according to claim 2, wherein before performing the data dimensionality reduction, the fault detection method further comprises:
performing missing value completion on the threshold voltage distribution data for each of a plurality of control lines of each of the plurality of control line types to obtain a completed distribution data,
wherein data dimensions corresponding to each of each control lines in the completed distribution data are the same, and
wherein the same data dimension represents a same number of sampling points.

4. The fault detection method according to claim 3, wherein the missing value completion comprises:
completing a missing value in the threshold voltage distribution data by interpolation; or based on a first data dimension of a first control line of a first control line type, among the plurality of control line types, being less than a maximum data dimension, completing the threshold voltage distribution data of the first control line by utilizing a default value such that a completed data dimension of the first control line is equal to a maximum data dimension,
wherein the maximum data dimension is a maximum voltage range covered by all control lines in the first control line type.

5. The fault detection method according to claim 2, wherein the performing the data dimensionality reduction comprises:
performing a statistical operation on the data in each of the plurality of data dimensions to obtain a statistical value of the data in the each data dimension; and
taking the statistical value of the data in each of the plurality of data dimensions as dimensionality reduced data for the respective data dimension after the data dimensionality reduction.

6. The fault detection method according to claim 1, wherein the predicting the possibility of failure of the one or more of the plurality of control line types based on the data feature of the one or more of the plurality of control line types to obtain the type prediction result comprises:
inputting the data feature of the one or more of the plurality of control line types into a corresponding type fault detection model, respectively, performing fault prediction through the corresponding type fault detection model, and obtaining the type prediction result of failure of the one or more of the plurality of control line types, respectively.

7. The fault detection method according to claim 6, wherein the type fault detection model of the plurality of control line types is trained and obtained by:
obtaining historical threshold voltage distribution data of the plurality of control line types and a historical type prediction result indicating a possibility of failure of the plurality of control line types;
extracting a sample data feature of the plurality of control line types from the historical threshold voltage distribution data; and
training to obtain the type fault detection model of the plurality of control line types by using the sample data feature of the plurality of control line types and the historical type prediction result,
wherein the historical threshold voltage distribution data comprises normal data in which a fault is absent, and fault data in which a fault is present.

8. The fault detection method according to claim 1, wherein the performing the fault detection operation comprises:
inputting the type prediction result of each of the one or more of the plurality of control line types into a fusion model,
performing fault detection through the fusion model, and
obtaining a fault detection result of the non-volatile memory.

9. The fault detection method according to claim 8, wherein the fusion model is trained and obtained by:
obtaining a historical type prediction result of each of the plurality of control line types of the non-volatile memory and a historical fault detection result of the non-volatile memory; and
training to obtain the fusion model by utilizing the historical type prediction result and the historical fault detection result.

10. The fault detection method according to claim 1, wherein the fault detection method further comprises:
based on detecting a presence of a fault in the non-volatile memory corresponding to a first control line type among the plurality of control line types:
performing abnormality scoring for each of a plurality of control lines of the first control line type to obtain an abnormality score of each of the plurality of control lines; and
based on a presence of a score mutation point in the abnormality scores of all of the plurality of control lines, identifying a first control line, among the plurality of control lines, with an abnormality score greater than the score mutation point as a bad line in the first control line type.

11. The fault detection method according to claim 10, wherein the performing abnormality scoring for each of the plurality of control lines comprises:
inputting the threshold voltage distribution data of each of the plurality of control lines into a scoring model,
performing abnormality scoring by the scoring model, and
obtaining the abnormality score of each of the plurality of control lines.

12. The fault detection method according to claim 11, wherein the scoring model is trained and obtained by:
obtaining historical normal threshold voltage distribution data of the non-volatile memory; and
training to obtain the scoring model by utilizing the historical normal threshold voltage distribution data in an unsupervised learning manner.

13. The fault detection method according to claim 1, wherein the non-volatile memory is a NAND flash solid state drive, and the threshold voltage distribution data is NAND threshold voltage distribution data.

14. A fault detection apparatus comprising:
a memory configured to store one or more instructions; and
one or more processors configured to executed the one or more instructions to:
obtain threshold voltage distribution data corresponding to a non-volatile memory;
obtain, based on the threshold voltage distribution data, a data feature of each of a plurality of control line types in the non-volatile memory;
predict a possibility of failure of one or more of the plurality of control line types based on the data feature of the one or more of the plurality of control line types, to obtain a type prediction result for the one or more of the plurality of control line types; and
perform a fault detection operation on in the non-volatile memory based on the type prediction result of each of the one or more of the plurality of control line types.

15. The fault detection apparatus according to claim 14, wherein the one or more processors is further configured to:
perform, based on the threshold voltage distribution data, data dimensionality reduction on data in each of a plurality of data dimensions for each of a plurality of control lines of each of the plurality of control line types.

16. The fault detection apparatus according to claim 15, wherein the one or more processors is further configured to:
before performing the data dimensionality reduction, perform missing value completion on the threshold voltage distribution data for each of a plurality of control lines of each of the plurality of control line types to obtain a completed distribution data,
wherein data dimensions corresponding to each of each control lines in the completed distribution data are the same, and
wherein the same data dimension represents a same number of sampling points.

17. The fault detection apparatus according to claim 16, wherein the missing value completion comprises:
completing a missing value in the threshold voltage distribution data by interpolation; or based on a first data dimension of a first control line of a first control line type, among the plurality of control line types, being less than a maximum data dimension, completing the threshold voltage distribution data of the first control line by utilizing a default value such that a completed data dimension of the first control line is equal to a maximum data dimension,
wherein the maximum data dimension is a maximum voltage range covered by all control lines in the first control line type.

18. The fault detection apparatus according to claim 15, wherein the one or more processors is further configured to:
perform a statistical operation on the data in each of the plurality of data dimensions to obtain a statistical value of the data in the each data dimension; and
take the statistical value of the data in each of the plurality of data dimensions as dimensionality reduced data for the respective data dimension after the data dimensionality reduction.

19. The fault detection apparatus according to claim 14, wherein the one or more processors is further configured to:
input the data feature of the one or more of the plurality of control line types into a corresponding type fault detection model, respectively, perform fault prediction through the corresponding type fault detection model, and
obtain the type prediction result of failure of the one or more of the plurality of control line types, respectively.

20-26. (canceled)

27. A non-transitory computer readable storage medium having stored thereon a computer program, which, when executed by a processor, is configured to implement a fault detection method comprising:
obtaining threshold voltage distribution data corresponding to a non-volatile memory;
obtaining, based on the threshold voltage distribution data, a data feature of each of a plurality of control line types in the non-volatile memory;
predicting a possibility of failure of one or more of the plurality of control line types based on the data feature of the one or more of the plurality of control line types, to obtain a type prediction result for the one or more of the plurality of control line types; and
performing a fault detection operation on the non-volatile memory based on the type prediction result of each of the one or more of the plurality of control line types.
